(19) United States
(12) Patent Application Publication
(10) Pub. No.: US 2019/0378883 A1
(43) Pub. Date: Dec. 12, 2019

(54) DISPLAY DEVICE

(71) Applicant: imat corporation, Hsinchu City (TW)

(72) Inventors: Tsai-An Yu, Hsinchu County (TW); Da-Ren Chiou, Taoyuan City (TW); Shih-Ming Hung, Hsinchu City (TW); Kuo-Chen Wu, Hsinchu City (TW); Hui-Mei Liu, Hsinchu County (TW); Hsiu-Yun Hsu, Hsinchu County (TW)

(73) Assignee: imat corporation, Hsinchu City (TW)

(21) Appl. No.: 16/120,473

(22) Filed: Sep. 4, 2018

(30) Foreign Application Priority Data
Jun. 8, 2018 (TW) 107119921

(51) Int. Cl. H01L 27/32; G02B 5/30; H01L 51/52

(52) U.S. Cl. CPC H01L 27/3232; H01L 51/5281; G02B 5/3016

(57) ABSTRACT

A display device is provided. The display device includes an organic light emitting diode display panel, a blue light brightness enhancement film and a polarizing film. The blue light brightness enhancement film is disposed on the organic light emitting diode display panel. The blue light brightness enhancement film includes a cholesteric liquid crystal layer and a quarter-wave phase retardation film, and the quarter-wave phase retardation film is disposed on the cholesteric liquid crystal layer. The polarizing film is disposed on the blue light brightness enhancement film.

### CROSS-REFERENCE TO RELATED APPLICATION

This application claims the priority benefit of Taiwan application serial no. 107119921, filed on Jun. 8, 2018. The entirety of the above-mentioned patent application is hereby incorporated by reference herein and made a part of this specification.

### BACKGROUND

### 1. Field of the Invention

The invention relates to a display device, and more particularly, to an organic light emitting diode display device.

### 2. Description of Related Art

An organic light emitting diode (OLED) display device belongs to a self-luminescent display device with the potential of becoming the mainstream of next-generation flat panel displays due to various advantages including no viewing-angle dependence, power-saving, simple process, low-cost, low operation temperature range, fast response speed, and full colorization. In general, by applying current to red, green, and blue organic light emitting materials, the OLED display device can convert electrical energy into a red light, a green light, and a blue light to emit a white light. Currently, the blue organic light emitting material has lower luminescent efficiency than the green and red organic light emitting materials. Therefore, when the white light is emitted from the OLED display device, the blue organic light emitting material is usually driven with a larger current so the brightness can be uniform. However, this approach would cause the blue organic light emitting material to decay faster than the red and green organic light emitting materials. When the blue organic light emitting material decays, the white light emitted from the OLED display device would suffer chromatic aberration which affects a picture quality and a service life.

### SUMMARY OF THE INVENTION

The invention provides a display device that can improve a utilization of the blue light to enhance a blue light brightness, thereby improving the service life of the display device.

The display device of the invention includes an organic light emitting diode display panel, a blue light brightness enhancement film and a polarizing film. The blue light brightness enhancement film is disposed on the organic light emitting diode display panel. The blue light brightness enhancement film includes a cholesteric liquid crystal layer and a quarter-wave phase retardation film, and the quarter-wave phase retardation film is disposed on the cholesteric liquid crystal layer. The polarizing film is disposed on the blue light brightness enhancement film.

In an embodiment of the invention, the blue light brightness enhancement film is located between the organic light emitting diode display panel and the polarizing film.

In an embodiment of the invention, the quarter-wave phase retardation film is located between the cholesteric liquid crystal layer and the polarizing film.

In an embodiment of the invention, a reflection center wavelength of the cholesteric liquid crystal layer is between 380 nm and 499 nm.

In an embodiment of the invention, a material of the quarter-wave phase retardation film includes a disk-like liquid crystal, a rod-like liquid crystal, and a rod-like liquid crystal doped with chiral molecule. An added amount of the chiral molecule is 0.01 to 3.0% of a solid content.

In an embodiment of the invention, the quarter-wave phase retardation film is a liquid crystal-based broadband phase retardation film.

In an embodiment of the invention, the display device further includes a first adhesive layer, which is disposed between the organic light emitting diode display panel and the blue light brightness enhancement film.

In an embodiment of the invention, the display device further includes a second adhesive layer, which is disposed between the blue light brightness enhancement film and the polarizing film.

In an embodiment of the invention, the blue light brightness enhancement film further includes a third adhesive layer, which is disposed between the cholesteric liquid crystal layer and the quarter-wave phase retardation film.

Based on the above, by including the organic light emitting diode display panel, the blue light brightness enhancement film disposed on the organic light emitting diode display panel and having the cholesteric liquid crystal layer and the quarter-wave phase retardation film stacked in sequence, as well as the polarizing film disposed on the blue light brightness enhancement film, the display device of the invention can enhance the blue light brightness. As a result, the service life of the display device can be improved.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a display device according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Herein, a range indicated by the wording “between a numerical value and another numerical value” is a schematic representation used to avoid listing all of the numerical values in that range in the specification. Therefore, the recitation of a specific numerical range covers any numerical value in the numerical range and a smaller numerical range defined by any numerical values in the numerical range, as is the case with any numerical value and a smaller numerical range thereof in the specification.

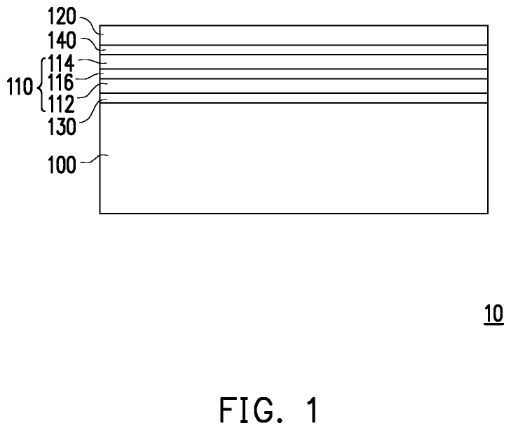

In order to provide a display device with the improved service life, the invention proposes a display device to achieve such advantage. An embodiment is described below with reference to FIG. 1 as an example to prove that the invention can indeed be realized.

FIG. 1 is a cross-sectional view of a display device according to an embodiment of the invention. With reference to FIG. 1, a display device 10 may include an organic light emitting diode display panel 100, a blue light brightness enhancement film 110, and a polarizing film 120. Here, the blue light brightness enhancement film 110 includes a cholesteric liquid crystal layer 112 and a quarter-wave phase retardation film 114. Further, in this embodiment, the display device 10 may optionally further include a first adhesive layer 130 and a second adhesive layer 140. Moreover, in this embodiment, the blue light brightness enhancement film 110 may optionally further include a third adhesive layer 116.

In this embodiment, the organic light emitting diode display panel 100 may be any organic light emitting diode display panel well-known to persons with ordinary skill in the art. Therefore, persons with ordinary skill in the art should understand the specific structure and operating principle of the organic light emitting diode display panel 100, which are not described in detail herein. For instance, the organic light emitting diode display panel 100 may include: a plurality of driving units and a plurality of light emitting elements disposed on a substrate. Each of the driving units may have, for example, 2T1C architecture, 1T1C architecture, 3T1C architecture, 3T2C architecture, 4T1C architecture, 4T2C architecture, 5T1C architecture, 5T2C architecture, 6T1C architecture, 6T2C architecture, 7T2C architecture, or any possible architecture. Each of the light emitting elements may include, for example, an anode, a cathode and a light emitting layer. The light emitting layer may include, for example, a red organic light emitting material, a green organic light emitting material or a blue organic light emitting material. In this embodiment, the organic light emitting diode display panel 100 is a self-luminescent display panel.

In this embodiment, the blue light brightness enhancement film 110 is disposed on the organic light emitting diode display panel 100. Specifically, in this embodiment, the blue light brightness enhancement film 110 is located between the organic light emitting diode display panel 100 and the polarizing film 120. Further, in this embodiment, the blue light brightness enhancement film 110 is used to enhance a brightness of a blue light emitted from the organic light emitting diode display panel 100. In other words, in this embodiment, the blue light brightness enhancement film 110 is located on a display side of the organic light emitting diode display panel 100.

In this embodiment, the cholesteric liquid crystal layer 112 is disposed on the organic light emitting diode display panel 100. In this embodiment, the cholesteric liquid crystal layer 112 is capable of reflecting a right circularly polarized light or a left circularly polarized light in a wavelength range in the vicinity of a reflection center wavelength. Specifically, in this embodiment, the reflection center wavelength of the cholesteric liquid crystal layer 112 may fall between 380 nm and 499 nm, and more preferably, between 430 nm and 480 nm. In other words, in this embodiment, the cholesteric liquid crystal layer 112 can reflect the right circularly polarized light or the left circularly polarized light of the blue light emitted from the organic light emitting diode display panel 100. Further, in this embodiment, the thickness of the cholesteric liquid crystal layer 112 is, for example, between 0.5 μm and 3.5 μm.

In this embodiment, the material of the cholesteric liquid crystal layer 112 may include a cholesteric liquid crystal, and the cholesteric liquid crystal may be (for example, but not limited to): a cholesteric liquid crystal molecule with a helical arrangement structure, a nematic liquid crystal molecule doped with chiral molecule, or a mixture of said two liquid crystal types. In an embodiment, the cholesteric liquid crystal molecule with the helical arrangement structure is (for example, but not limited to): the reactive cholesteric liquid crystal monomer produced by Orgchem Technologies, Inc. In an embodiment, the nematic liquid crystal molecule is (for example, but not limited to): LC1057 or LC242 produced by BASF Corp. The chiral molecule is, for example, LC756 produced by BASF Corp. Further, in an embodiment, if the cholesteric liquid crystal in the cholesteric liquid crystal layer 112 has a right helical structure, the cholesteric liquid crystal layer 112 reflects the right circularly polarized light in the reflection center wavelength. Naturally, in another embodiment, if the cholesteric liquid crystal in the cholesteric liquid crystal layer 112 has a left helical structure, the cholesteric liquid crystal layer 112 reflects the left circularly polarized light in the reflection center wavelength.

In this embodiment, the quarter-wave phase retardation film 114 is disposed on the cholesteric liquid crystal layer 112. Specifically, in this embodiment, the quarter-wave phase retardation film 114 is capable of converting the circularly polarized light into a linearly polarized light in line with a light transmission axis of the polarizing film 120. On that basis, in this embodiment, the quarter-wave phase retardation film 114 is located between the cholesteric liquid crystal layer 112 and the polarizing film 120. In this embodiment, the thickness of the quarter-wave phase retardation film 114 is, for example, between 1 μm and 10 μm.

In this embodiment, the material of the quarter-wave phase retardation film 114 includes (for example, but not limited to): a disk-like liquid crystal, a rod-like liquid crystal or a rod-like liquid crystal doped with chiral molecule. The added amount of the chiral molecule is approximately 0.01 to 3.0% of a solid content. In this embodiment, the quarter-wave phase retardation film 114 may be a single-layer structure or a multi-layer structure. In an embodiment, the quarter-wave phase retardation film 114 may be a liquid crystal-based broadband phase retardation film, and the liquid crystal-based broadband phase retardation film may include two phase retardation films stacked on each other. The in-plane phase difference Ro of one of said two phase retardation films is between 70 nm and 130 nm, the in-plane phase difference Ro of the other phase retardation film is between 140 nm and 260 nm, and an included angle between the optic axis of one of said two phase retardation films and the optic axis of the other phase retardation film is between 35° and 70°. Also, materials of the two phase retardation films may include a disk-like liquid crystal, a rod-like liquid crystal or a rod-like liquid crystal doped with chiral molecule. The added amount of the chiral molecule is 0.01 to 3% of a solid content. In other words, in this embodiment, the quarter-wave phase retardation film 114 may belong to a polymer liquid crystal thin film. In an embodiment, the disk-like liquid crystal is (for example, but not limited to): the discotic liquid crystal produced by Shijiazhuang Slichem Display Material Co., Ltd In an embodiment, the rod-like liquid crystal is (for example, but not limited to): LC1057 or LC242 produced by BASF Corp. In an embodiment, the rod-like liquid crystal is (for example, but not limited to): LC1057 or LC242 produced by BASF Corp., and the chiral molecule is (for example, but not limited to): LC756 produced by BASF Corp.

As described above, since the quarter-wave phase retardation film 114 may be formed by a liquid crystal material, the cholesteric liquid crystal layer 112 and the quarter-wave phase retardation film 114 may both be made by adopting a roll-to-roll coating process to thereby improve a productivity of the blue light brightness enhancement film 110.

In this embodiment, the first adhesive layer 130 is disposed between the organic light emitting diode display panel 100 and the blue light brightness enhancement film 110. In other words, the organic light emitting diode display panel 100 and the blue light brightness enhancement film 110 are bonded together through the first adhesive layer 130. However, the invention is not limited in this regard. In other embodiments, the organic light emitting diode display panel 100 and the blue light brightness enhancement film 110 may be in direct contact with each other without being interposed with other film layers. In this embodiment, the material of the first adhesive layer 130 may include (but not limited to): a liquid optically clear adhesive (LOCA), a pressure sensitive adhesive (PSA), a hydrogel or a UV adhesive. Further, in this embodiment, the thickness of the first adhesive layer 130 is, for example, between 5 nm to 25 μm.

In this embodiment, the polarizing film 120 may be any polarizing film used in the organic light emitting diode display panel and well-known to persons with ordinary skill in the art. Therefore, persons with ordinary skill in the art should understand the specific structure and preparing method of the polarizing film 120, which are not described in detail herein. For instance, the polarizing film 120 may include, for example, a polarizer and a protective film located on two sides of the polarizer. Here, for example, said polarizer may be a polyvinyl alcohol film absorbed with dichroic dye and may be made through the following step. After the polyvinyl alcohol film is dyed with a dichroic substance such as an iodine dye, the dyed polyvinyl alcohol film is then stretched in a predetermined direction. The material of the protective film may include, for example, triacetate cellulose (TAC), cyclo olefin polymer (COP) or polyethylene terephthalate (PET).

In this embodiment, the second adhesive layer 140 is disposed between the blue light brightness enhancement film 110 and the polarizing film 120. In other words, the blue light brightness enhancement film 110 and the polarizing film 120 are bonded together through the second adhesive layer 140. However, the invention is not limited in this regard. In other embodiments, the blue light brightness enhancement film 110 and the polarizing film 120 may be in direct contact with each other without being interposed with other film layers. In other embodiments, an adhesion promoter layer capable of adhering to both the blue light brightness enhancement film 110 and the second adhesive layer 140 may be further provided between the blue light brightness enhancement film 110 and the second adhesive layer 140. That is to say, the blue light brightness enhancement film 110 and the polarizing film 120 are boned together through the second adhesive layer 140 and the adhesion promoter layer. In this embodiment, the material of the second adhesive layer 140 may include (but not limited to): a liquid optically clear adhesive (LOCA), a pressure sensitive adhesive (PSA), a hydrogel or a UV adhesive. Further, in this embodiment, a thickness of the second adhesive layer 140 is, for example, between 5 nm to 25 μm.

In this embodiment, the third adhesive layer 116 is disposed between the cholesteric liquid crystal layer 112 and the quarter-wave phase retardation film 114. In other words, the cholesteric liquid crystal layer 112 and the quarter-wave phase retardation film 114 are bonded together through the third adhesive layer 116. However, the invention is not limited in this regard. In other embodiments, the cholesteric liquid crystal layer 112 and the quarter-wave phase retardation film 114 may be in direct contact with each other without being interposed with other film layers. It is worth noting that, since the quarter-wave phase retardation film 114 may be formed by a liquid crystal material, when the cholesteric liquid crystal layer 112 and the quarter-wave phase retardation film 114 are in direct contact with each other, the quarter-wave phase retardation film 114 can be formed by a coating process directly performed on the cholesteric liquid crystal layer 112, or the cholesteric liquid crystal layer 112 can be formed by a coating process directly performed on the quarter-wave phase retardation film 114. In other embodiments, an adhesion promoter layer capable of adhering to both the cholesteric liquid crystal 112 and the third adhesive layer 116 may be further provided between the quarter-wave phase retardation film 114 and the third adhesive layer 116. That is to say, the cholesteric liquid crystal layer 112 and the quarter-wave phase retardation film 114 are boned together through the third adhesive layer 116 and the adhesion promoter layer. In this embodiment, the material of the third adhesive layer 116 may include (but not limited to): a liquid optically clear adhesive (LOCA), a pressure sensitive adhesive (PSA), a hydrogel or a UV adhesive. Further, in this embodiment, a thickness of the third adhesive layer 116 is, for example, between 5 nm to 25 μm.

It should be noted that, by including the organic light emitting diode display panel 100, the blue light brightness enhancement film 110 disposed on the organic light emitting diode display panel 100 and having the cholesteric liquid crystal layer 112 and the quarter-wave phase retardation film 114 stacked in sequence, as well as the polarizing film 120 disposed on the blue light brightness enhancement film 110, the display device 10 can improve the utilization of the blue light emitted by the organic light emitting diode display panel 100 to thereby enhance the blue light brightness of the display device 10. Based on the description above, why the blue light brightness of the display device 10 can be enhanced at least includes the following reasons. [1] The blue light brightness enhancement film 110 disposed on the organic light emitting diode display panel 100 and having the cholesteric liquid crystal layer 112 can separate the left circularly polarized light and the right circularly polarized light from the blue light emitted from the organic light emitting diode display panel, and one of the left circularly polarized light and the right circularly polarized light can pass through the cholesteric liquid crystal layer 112, whereas the other one would be reflected by the cholesteric liquid crystal layer 112. After being reflected by any reflection surface (e.g., electrodes, circuits) in the organic light emitting diode display panel 100, the circularly polarized light reflected by the cholesteric liquid crystal layer 112 is then converted into the circularly polarized light capable of passing through the cholesteric liquid crystal layer 112 so a light transmittance of the blue light can be improved. [2] By including the quarter-wave phase retardation film 114 disposed on the cholesteric liquid crystal layer 112, the blue light brightness enhancement film 110 can convert the entire blue light (the circularly polarized lights) passed through the cholesteric liquid crystal layer 112 into the linearly polarized light in line with the transmission axis of the polarizing film 120 so the utilization of the blue light can be prevented from being reduced by a light absorbance of the polarizing film 120. Accordingly, compared to the conventional display device, a lower driving voltage may be used to drive the blue organic light emitting material to slow down a decay speed of the blue organic light emitting material in use of the display device 10 to thereby improve the service life of the display device 10.

Hereinafter, features of the invention are specifically described below with reference to Example 1, Example 2, Comparative Example 1 and Comparative Example 2. Although the following embodiments are described, modification can be made without departing from the scope of the invention, and the invention should not be limitedly interpreted by the embodiments described below.

### Example 1

A display device of Example 1 is manufactured by bonding a blue light brightness enhancement film with an organic light emitting diode display panel (produced by RiTdisplay Co., Ltd.) through a pressure sensitive adhesive and bonding a polarizing film (produced by BenQ Material Corp.) with the blue light brightness enhancement film through a pressure sensitive adhesive. Here, the blue light brightness enhancement film includes a liquid crystal-based broadband phase retardation film (produced by Imat Co. Ltd.) and a cholesteric liquid crystal layer (produced by Imat Co. Ltd.) bonded together through a UV adhesive.

### Example 2

A display device of Example 2 is manufactured by bonding a blue light brightness enhancement film with an organic light emitting diode display panel (produced by Tianma Microelectronics Co., Ltd.) through a pressure sensitive adhesive and bonding a polarizing film (produced by Sunnypol Optoelectronics Co., Ltd.) with the blue light brightness enhancement film through a pressure sensitive adhesive. Here, the blue light brightness enhancement film includes a liquid crystal-based broadband phase retardation film (produced by Imat Co., Ltd.) and a cholesteric liquid crystal layer (produced by Imat Co., Ltd.) bonded together through a UV adhesive.

### Comparative Example 1

A display device of Comparative Example 1 is similar to the display device of Example 1 except that the display device of Comparative Example 1 is not disposed with the blue light brightness enhancement film.

### Comparative Example 2

A display device of Comparative Example 2 is similar to the display device of Example 2 except that the display device of Comparative Example 2 is not disposed with the blue light brightness enhancement film.

Measurements are conducted using a Spectroradiometer (manufactured by Topcon Corp.; model number: SR-3) on the blue light brightness in front of each of the display devices in Embodiments 1 and 2 and Comparative Examples 1 and 2 by distance of 1 m in dark chamber. The measurement results are shown in Table 1.

TABLE 1

| | | Comparative | | Comparative |
|---|---|---|---|---|
| | Example 1 | Example 1 | Example 2 | Example 2 |
| Blue light | 26.23 | 23.26 | 23.57 | 20.87 |
| brightness | | | | |
| (cd/m²) | | | | |

| | | |
|---|---|---|
| Increased | 12.8 | 12.9 |
| brightness (%) | | |

In view of Table 1 above, the display device of Example 1 has a stronger blue light brightness compared to the display device of Comparative Example 1, and the display device of Example 2 has a stronger blue light brightness compared to the display device of Comparative Example 2. The results indicate that, by including the organic light emitting diode display panel, the blue light brightness enhancement film disposed on the organic light emitting diode display panel and having the cholesteric liquid crystal layer and the quarter-wave phase retardation film stacked in sequence, as well as the polarizing film disposed on the blue light brightness enhancement film, the display device of the invention can enhance the blue light brightness.

Although the present disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

What is claimed is:

1. A display device, comprising:
an organic light emitting diode display panel;
a blue light brightness enhancement film, disposed on the organic light emitting diode display panel, wherein the blue light brightness enhancement film comprises a cholesteric liquid crystal layer and a quarter-wave phase retardation film, and the quarter-wave phase retardation film is disposed on the cholesteric liquid crystal layer; and
a polarizing film, disposed on the blue light brightness enhancement film.

2. The display device according to claim 1, wherein the blue light brightness enhancement film is located between the organic light emitting diode display panel and the polarizing film.

3. The display device according to claim 1, wherein the quarter-wave phase retardation film is located between the cholesteric liquid crystal layer and the polarizing film.

4. The display device according to claim 1, wherein a reflection center wavelength of the cholesteric liquid crystal layer is between 380 nm and 499 nm.

5. The display device according to claim 1, wherein a material of the quarter-wave phase retardation film comprises a disk-like liquid crystal, a rod-like liquid crystal, and a rod-like liquid crystal doped with chiral molecule, wherein an added amount of the chiral molecule is 0.01 to 3.0% of a solid content.

6. The display device according to claim 1, wherein the quarter-wave phase retardation film is a liquid crystal-based broadband phase retardation film.

7. The display device according to claim 1, further comprising: a first adhesive layer, disposed between the organic light emitting diode display panel and the blue light brightness enhancement film.

8. The display device according to claim 1, further comprising: a second adhesive layer, disposed between the blue light brightness enhancement film and the polarizing film.

9. The display device according to claim 1, wherein the blue light brightness enhancement film further comprises a third adhesive layer, disposed between the cholesteric liquid crystal layer and the quarter-wave phase retardation film.
